(19) United States
(12) Patent Application Publication
(10) Pub. No.: US 2012/0241838 A1
(43) Pub. Date: Sep. 27, 2012

(54) SEMICONDUCTOR STORAGE DEVICE AND METHOD FOR MANUFACTURING THE SAME

(75) Inventors: Hidenobu NAGASHIMA, Mie (JP); Akira YOTSUMOTO, Mie (JP)

(73) Assignee: Kabushiki Kaisha Toshiba, Tokyo (JP)

(21) Appl. No.: 13/422,547

(22) Filed: Mar. 16, 2012

(30) Foreign Application Priority Data
Mar. 24, 2011 (JP) 2011-066623

(51) Int. Cl. H01L 29/788; H01L 21/768

(52) U.S. Cl. 257/316; 438/421; 257/E29.3; 257/E21.581

(57) ABSTRACT

According to one embodiment, a semiconductor storage device includes: a plurality of word lines that are formed at predetermined intervals in a first direction on the element region; a select gate transistor that is arranged in each of both sides of the word lines and has a width in the first direction wider than the word line; a first air gap that is positioned between the word lines; and a second air gap that is formed on a side wall portion opposite to a side of the word line of the select gate transistor. Further, according to one embodiment, the semiconductor storage device is provided in which an oxide film is formed on a surface of a substrate between the select gate transistors that are adjacent to each other, and a cross-sectional surface in a direction perpendicular to the first direction under the oxide film has a convex shape.

### CROSS-REFERENCE TO RELATED APPLICATIONS

This application is based upon and claims the benefit of priority from Japanese Patent Application No. 2011-066623, filed on Mar. 24, 2011; the entire contents of which are incorporated herein by reference.

### FIELD

Embodiments described herein generally relate to a semiconductor storage device and a method for manufacturing the same.

### BACKGROUND

In development of a semiconductor storage device, the miniaturization of elements to achieve a large capacity and low cost has been advanced year by year. For example, in an NAND flash memory device, the miniaturization of wiring pitches such as a bit line and a word line is advanced. In the case of manufacturing such a semiconductor storage device, when processing of opening a bit-line contact hole pattern is performed, a resist is opened by a lithography technique and processing is performed by a reactive ion etching (hereinafter referred to as “RIE”) method. At that time, when misalignment occurs in the lithography or processing in the RIE method has variations, the distance between the bit line contact and its adjacent element region becomes short. Thus, if the adjacent distance becomes short, there arises a problem that breakdown is caused when an operating voltage is applied, and the adjacent bit line is short-circuited.

Also, in a nonvolatile semiconductor storage device of the related art, an inter-word line is filled with an oxide film or a nitride film. However, there is a problem that a word line interval becomes short with element miniaturization and the writing speed degrades due to a parasitic capacity caused between floating gate electrodes or between a floating gate and a diffusion layer in an adjacent word line, which is so-called “Yupin/Enda effect.” To solve such a problem, a method is proposed that a parasitic capacity is reduced by accumulating oxide films having a poor filling characteristic in a word line and between word lines and providing an air gap (i.e. hollow) between adjacent floating gate electrodes.

However, when an air gap forming method of the related art is applied, an air gap is formed in a side wall portion of a select gate transistor. In this configuration, when the distance between the select gate transistor and the bit line contact is shortened, the bit line contact hole and the air gap become in contact with each other at the time of processing the bit line contact hole and the air gap is filled with an electrical conducting material at the time of filling the bit line contact hole with the electrical conducting material, and therefore there is a possibility that the bit line contact hole and its adjacent bit line contact hole are short-circuited via the air gap. Therefore, there is a problem that it is not possible to shorten the distance between select gates and reduce a semiconductor device area. Also, with miniaturization, a more advantageous configuration is demanded to maintain the pressure resistance between an adjacent element region and a contact hole.

### BRIEF DESCRIPTION OF THE DRAWINGS

FIG. 1 is a view illustrating one process of a manufacture method for a semiconductor storage device according to first and second embodiments;

FIG. 2 is a view illustrating one process of a manufacture method for a semiconductor storage device according to the first and second embodiments;

FIGS. 3A to 3C are views illustrating one process of a manufacture method for a semiconductor storage device according to the first and second embodiments;

FIG. 4 is a view illustrating one process of a manufacture method for a semiconductor storage device according to the first and second embodiments;

FIG. 5 is a view illustrating one process of a manufacture method for a semiconductor storage device according to the first embodiment;

FIG. 6 is a view illustrating one process of a manufacture method for a semiconductor storage device according to the first embodiment;

FIG. 7 is a view illustrating one process of a manufacture method for a semiconductor storage device according to the first embodiment;

FIG. 8 is a view illustrating one process of a manufacture method for a semiconductor storage device according to the first embodiment;

FIG. 9 is a view illustrating one process of a manufacture method for a semiconductor storage device according to the first embodiment;

FIG. 10 is a view illustrating one process of a manufacture method for a semiconductor storage device according to the first embodiment;

FIG. 11 is a view illustrating one process of a manufacture method for a semiconductor storage device according to the first embodiment;

FIG. 12 is a view illustrating one process of a manufacture method for a semiconductor storage device according to the first embodiment;

FIG. 13 is a view illustrating one process of a manufacture method for a semiconductor storage device according to the first embodiment;

FIG. 14 is a view illustrating one process of a manufacture method for a semiconductor storage device according to the second embodiment;

FIG. 15 is a view illustrating one process of a manufacture method for a semiconductor storage device according to the second embodiment;

FIG. 16 is a view illustrating one process of a manufacture method for a semiconductor storage device according to the second embodiment;

FIG. 17 is a view illustrating one process of a manufacture method for a semiconductor storage device according to the second embodiment;

FIG. 18 is a view illustrating one process of a manufacture method for a semiconductor storage device according to the second embodiment;

FIG. 19 is a view illustrating one process of a manufacture method for a semiconductor storage device according to the second embodiment;

FIG. 20 is a view illustrating one process of a manufacture method for a semiconductor storage device according to the second embodiment;

FIG. 21 is a view illustrating one process of a manufacture method for a semiconductor storage device according to the second embodiment;

FIG. 22 is a view illustrating one process of a manufacture method for a semiconductor storage device according to the second embodiment; and

FIG. 23 is a view illustrating one process of a manufacture method for a semiconductor storage device according to the second embodiment.

### DETAILED DESCRIPTION

According to one embodiment, a semiconductor storage device includes: a plurality of element isolation regions that are formed on a semiconductor substrate and extended along a first direction in parallel; a first insulating film that is formed on an element region between the adjacent element isolation regions on the semiconductor substrate; a plurality of word lines that are formed at predetermined intervals in the first direction on the element region and have a charge accumulation layer, a second insulating film and a control gate electrode that are layered in order on the first insulating film; a select gate transistor that is arranged in each of both sides of the plurality of word lines and has a width in the first direction wider than the word line; an interlayer insulating film that is formed to cover an upper surface of the word line and the select gate transistor; a first air gap that is positioned between the word lines and has an upper surface covered with the interlayer insulating film; and a second air gap that is formed on a side wall portion opposite to a side of the word line of the select gate transistor and has an upper surface covered with the interlayer insulating film. Further, according to one embodiment, the semiconductor storage device is provided in which an oxide film is formed on a surface of the semiconductor substrate between the select gate transistors that are adjacent to each other, and a cross-sectional surface in a second direction perpendicular to the first direction under the oxide film has a convex shape.

Exemplary embodiments of the semiconductor storage device and the manufacture method for the same will be explained below in detail with reference to the accompanying drawings. The present invention is not limited to the following embodiments.

### First Embodiment

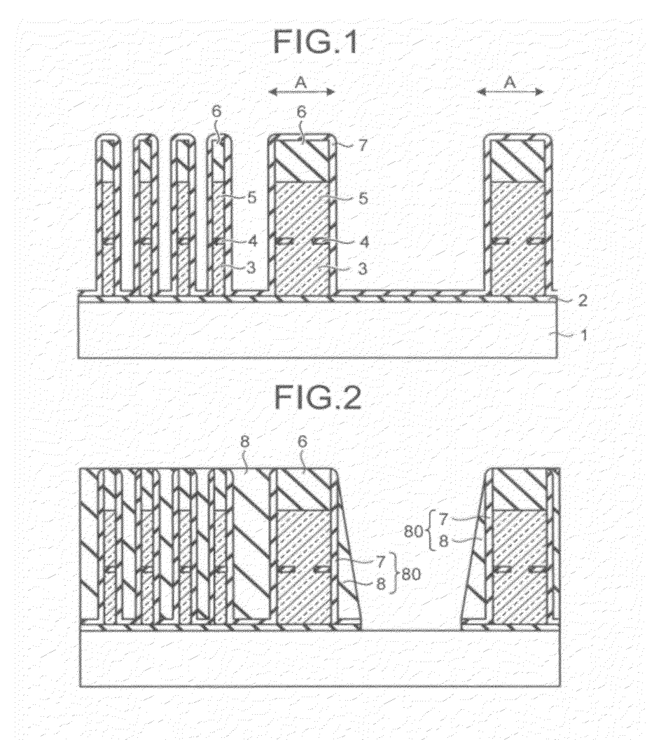

FIGS. 1 to 13 illustrate each process of a manufacture method for a semiconductor storage device according to the present embodiment. FIGS. 1, 2, 3A and 4 to 13 are cross-sectional views where the paper perpendicular direction is a word line direction of a nonvolatile semiconductor storage device.

FIG. 1 illustrates a state where word line processing is already performed. Up to word line processing, a known method is applicable. For example, a tunnel oxide film 2 (first insulating film) formed with a silicon oxide film and a floating gate electrode 3 (charge accumulation layer) formed with a polysilicon film are formed on a semiconductor substrate 1.

In the word line direction (or paper perpendicular direction) in FIG. 1, the floating gate electrode 3, the tunnel oxide film 2 and the semiconductor substrate 1 are removed at predetermined intervals to form a groove along the paper horizontal direction of the bit line direction (or first direction) (not shown). By filling this groove with a silicon oxide film up to a predetermined height, an element isolation region (not shown) is formed.

An interpoly insulating film 4 (second insulating film) is formed to cover the floating gate electrode 3 and the element isolation region. Further, a first polysilicon film is formed on the interpoly insulating film 4. In a region in which a select gate transistor and a peripheral transistor are formed, for example, in region A of FIG. 1, the first polysilicon film in a predetermined portion and part of the interpoly insulating film 4 are removed to form a groove. A second polysilicon film is formed on the first polysilicon film to fill this groove.

In a memory cell array unit, a control gate electrode 5 is formed with the first polysilicon film and the second polysilicon film. Also, in the select gate transistor and the peripheral transistor, an etching interpoly configuration (such as region A) is provided in which a polysilicon film (i.e. the control gate electrode 5) above the interpoly insulating film 4 and a polysilicon film (i.e. the floating gate electrode 3) below the interpoly insulating film 4 are connected.

A silicon nitride film 6 is formed on the control gate electrode 5. Then, in the bit line direction (or first direction) at predetermined intervals, the silicon nitride film 6, the control gate electrode 5, the interpoly insulating film 4 and the floating gate electrode 3 are removed along the word line direction (or paper perpendicular direction) to perform word line processing. Here, the select gate transistor shown in region A is arranged in each of the both ends of word lines. Generally, the width in the bit line direction of the select gate transistor is wider than the width in the bit line direction of the word line and is preferably three or more times as wide as the width in the bit line direction of the word line.

As illustrated in FIG. 1, after word line processing is performed, a spacer oxide film 7 (i.e. silicon oxide film) is formed and impurity implantation is performed to form a diffusion layer (not shown) in a semiconductor substrate surface portion.

Then, the spacer oxide film 7 is covered as illustrated in FIG. 2 to form a sacrifice nitride film 8 (i.e. silicon nitride film) to fill a gap between word lines. It is preferable to form the spacer oxide film 7 and the sacrifice nitride film 8 by an ALD (Atomic Layer Deposition) method. The sacrifice nitride film 8 may be formed by an LP-CDV method or a plasma CVD method.

Further, as illustrated in FIG. 2, the sacrifice nitride film 8 is subjected to etch back by RIE (reactive ion etching) to form a side wall film 80 on a side wall portion of the select gate transistor. The side wall film 80 is formed with the sacrifice nitride film 8 and the spacer oxide film 7. By this etch back, the spacer oxide film 7 and the tunnel oxide film 2 are removed and an upper surface of the silicon nitride film 6 and a surface of the semiconductor substrate 1 between select gate transistors are exposed.

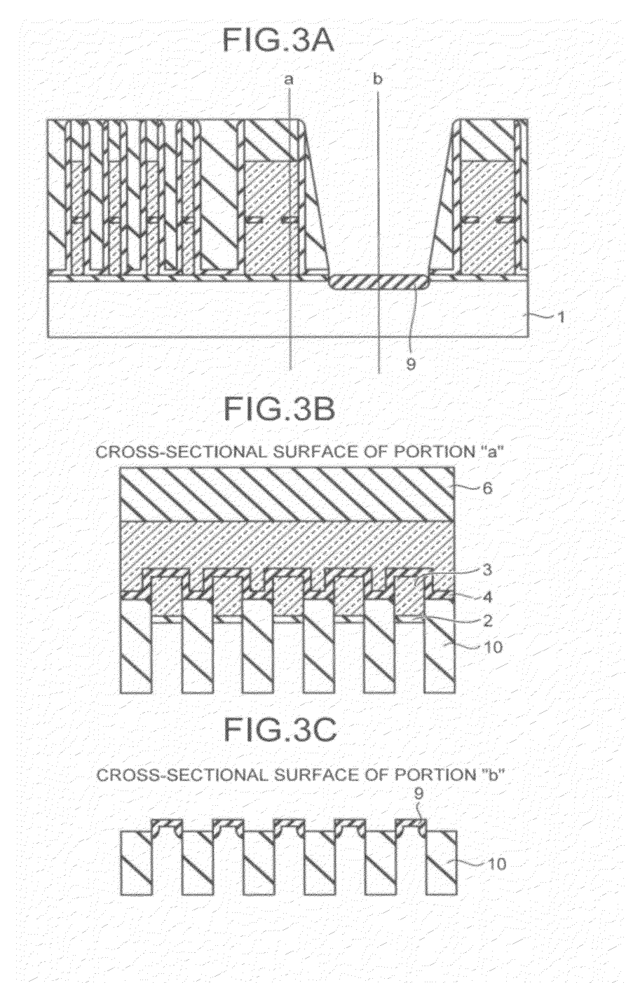

Next, as illustrated in FIG. 3A, the surface of the silicon substrate 1 that is an element region between the select gate transistors is thermally oxidized to form an oxide film 9. Here, a word-line-direction cross-sectional view of portion “a” in FIG. 3A is illustrated in FIG. 3B, and the word-line-direction cross-sectional view of portion “b” in FIG. 3A is illustrated in FIG. 3C. As illustrated in FIG. 3C, the oxide film 9 is formed on the surface of the silicon substrate 1 of the element region. By an oxidizing agent provided through an element isolation region 10, the shape of the element region becomes a convex shape with respect to the word-line-direction cross-sectional surface. By forming the convex shape, it is possible to widen the distance from an adjacent element region and a contact.

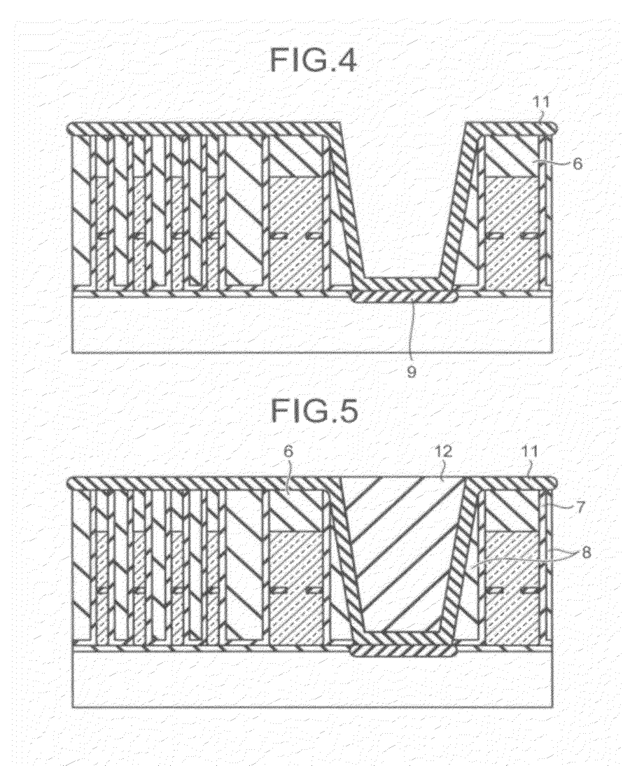

Next, as illustrated in FIG. 4, a contact processing stopper nitride film 11 (i.e. silicon nitride film) is formed.

Next, as illustrated in FIG. 5, an interlayer oxide film 12 is formed to fill a gap between select gate transistors. The interlayer oxide film 12 is preferably a silicon oxide film having a wet etching selectivity with the sacrifice nitride film 8 between the word lines. Then, using the silicon nitride film 6 as a stopper, planarization processing is performed by CMP (Chemical Mechanical Polishing) (not shown).

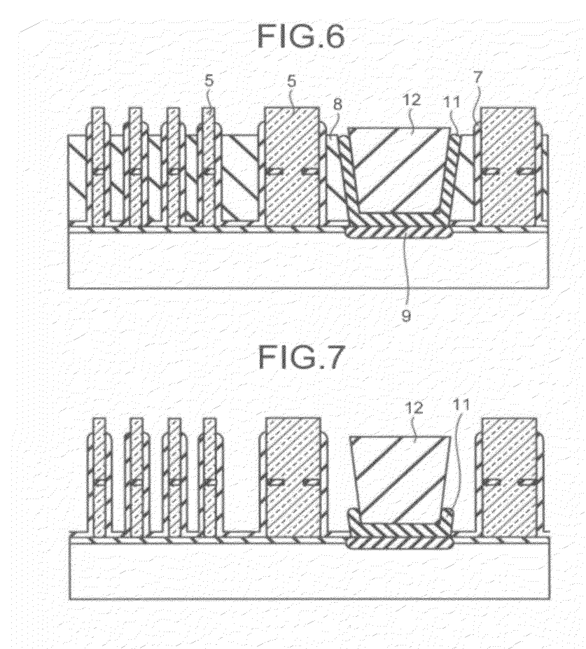

Next, as illustrated in FIG. 6, the silicon nitride film 6 is removed by RIE to expose an upper surface of the control gate electrode 5. At the time of removing the silicon nitride film 6, the spacer oxide film 7, the contact processing stopper nitride film 11 and the interlayer oxide film 12 are also removed more or less.

Next, as illustrated in FIG. 7, the sacrifice nitride film 8 is removed by wet etching or CDE (Chemical Dry Etching). At this time, the contact processing stopper nitride film 11 of other portions than the portion below the interlayer oxide film 12 between the select gate transistors is also removed.

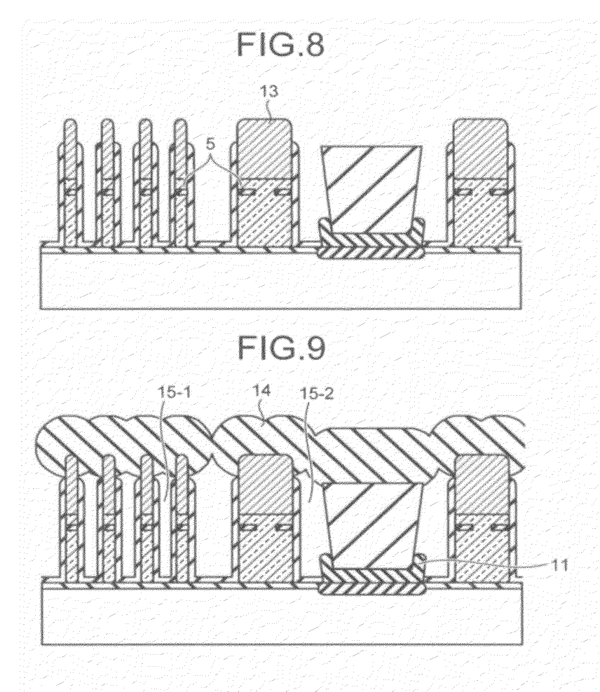

Next, as illustrated in FIG. 8, at least part of the control gate electrode 5 is made to be a silicide 13. As a silicide metal material, it is possible to use transition metals of groups 4 to 11 such as Ni, Ti, Co, Pt, Pd, Ta and Mo.

Next, as illustrated in FIG. 9, a silicon oxide film 14 is formed by a plasma CVD method. The plasma CVD method is a deposition method with a poor implantation characteristic, and therefore regions, in which the sacrifice nitride film 8 and the contact processing stopper nitride film 11 are removed, are not filled, so that it is possible to provide these regions as air gaps 15-1 and 15-2. By this means, it is possible to form the air gap 15-1 between the word lines and form the air gap 15-2 on a side wall portion of the select gate transistor.

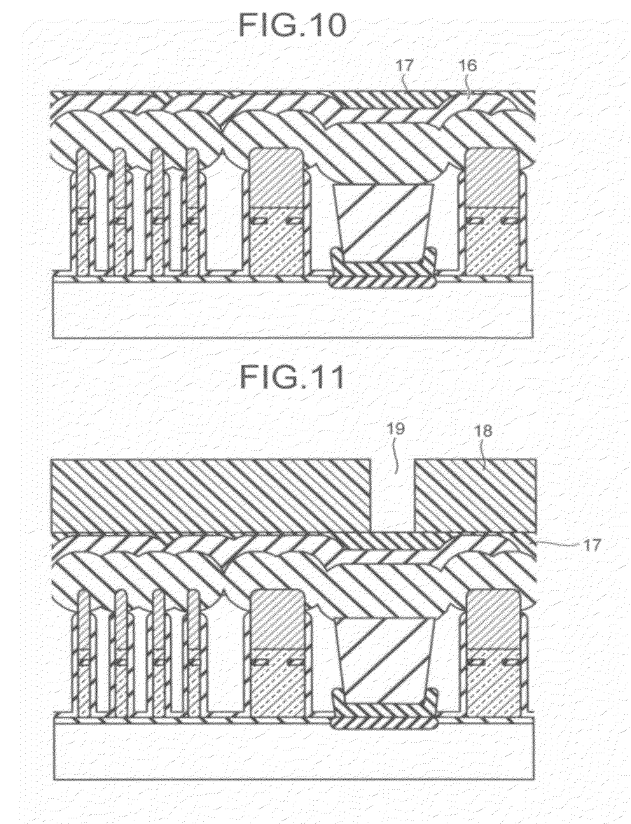

Next, as illustrated in FIG. 10, a CMP stopper nitride film 16 (i.e. silicon nitride film) and an interlayer insulating film 17 (i.e. silicon oxide film) are formed. Further, by CMP, the interlayer insulating film 17 is polished and planarization processing is performed using the silicon nitride film 16 as a stopper.

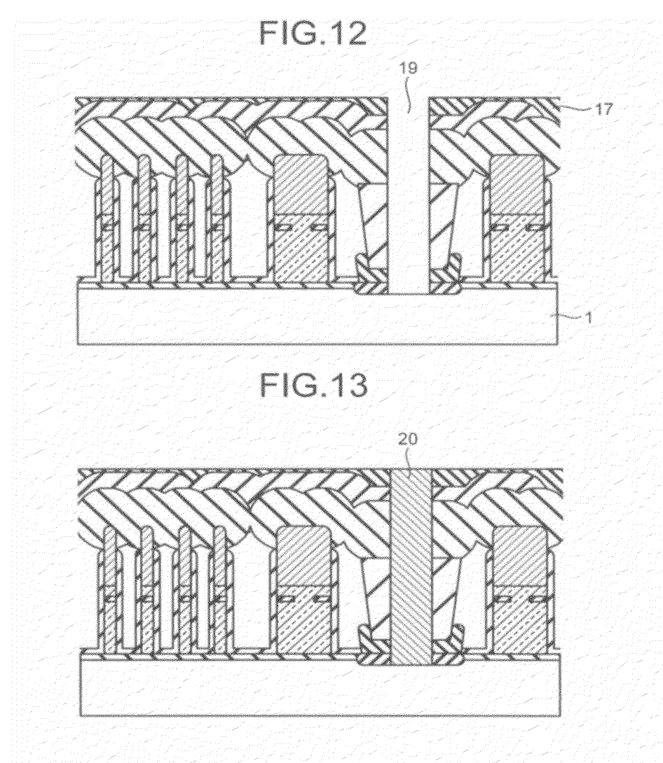

Next, as illustrated in FIG. 11, a photoresist film 18 is applied and processed by a normal lithography technique to form a hole pattern 19 for bit line contact formation. Further, as illustrated in FIG. 12, using the photoresist film 18 as a mask, the hole pattern 19 is processed by RIE to penetrate to the semiconductor substrate 1 through an SiO₂ film of the interlayer insulating film 17 and its lower layers. For example, by asking processing, the photoresist 18 is removed.

Finally, as illustrated in FIG. 13, a wiring metal 20 such as tungsten is formed by a CVD method in the bit line contact portion to form a bit line contact.

Unlike the present embodiment, in the process of forming the oxide film 9 in FIGS. 3A to 3C, if an oxide film is formed on the entire surface of the sacrifice nitride film 8 using, for example, CVD, a footless oxide film remains in etching removal of the sacrifice nitride film 8 and the contact processing stopper nitride film 11 in FIG. 7. For example, if this oxide film drops, it becomes a dust as an obstructive factor in silicidation in FIG. 8. However, according to the manufacture method for the semiconductor storage device of the present embodiment described above, by forming the oxide film 9 by thermal oxidation between the select gate transistors except for a portion on the sacrifice nitride film 8, it is possible to solve this problem. Further, by forming the air gap 15 between adjacent word lines and widening the distance between the contact hole and an element region between the select gate transistors, the semiconductor storage device of the present embodiment provides an advantageous configuration for pressure resistance maintenance between the adjacent element region and the contact hole.

### Second Embodiment

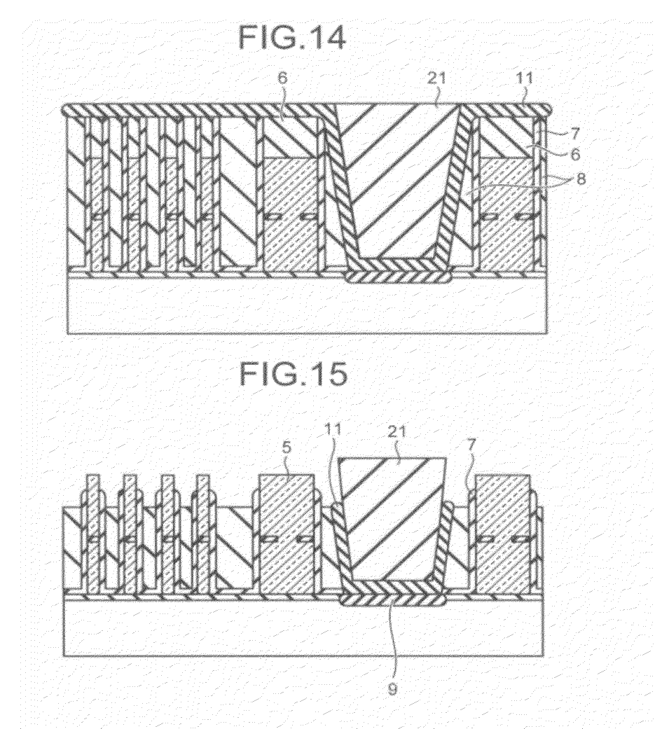

In a manufacture method for a semiconductor storage device according to the present embodiment, the process up to FIG. 4 is the same as in the first embodiment. FIGS. 14 to 23 illustrate each process of the manufacture method after FIG. 4 for the semiconductor storage device according to the present embodiment. FIGS. 14 to 23 are cross-sectional views where the paper perpendicular direction is a word line direction of a nonvolatile semiconductor storage device.

After FIG. 4, as illustrated in FIG. 14, an interlayer sacrifice film 21 is formed to fill a gap between the select gate transistors. It is preferable that the interlayer sacrifice film 21 is a carbon-type coating film or BPSG (Boron Phosphorus Silicon Glass) film that is easily dissolved by wet etching. Then, using the silicon nitride film 6 as a stopper, planarization processing is performed by CMP (Chemical Mechanical Polishing) (not shown).

Next, as illustrated in FIG. 15, the silicon nitride film 6 is removed by RIB to expose an upper surface of the control gate electrode 5. At the time of removing the silicon nitride film 6, the spacer oxide film 7, the contact processing stopper nitride film 11 and the interlayer sacrifice film 21 are also removed more or less.

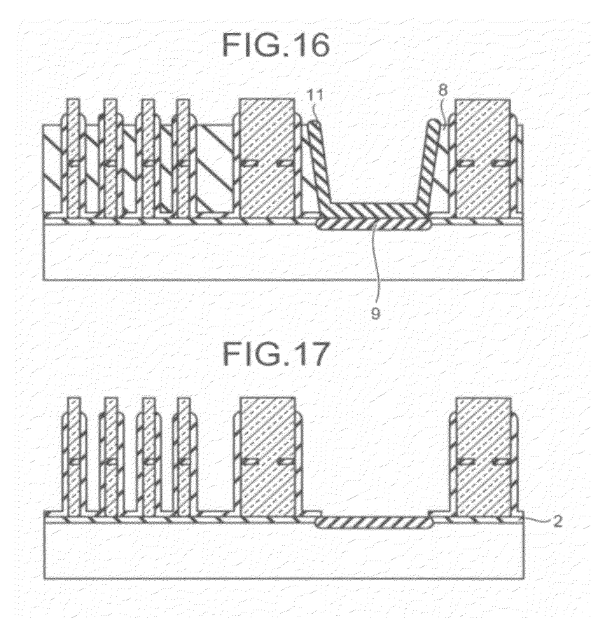

Next, as illustrated in FIG. 16, the interlayer sacrifice film 21 is removed by wet etching. At this time, when the interlayer sacrifice film 21 is a carbon-type coating film, it is removed by asking processing, for example. In the case of a BPSG film, it is removed by wet etching.

Next, as illustrated in FIG. 17, the sacrifice nitride film 8 is removed by wet etching or CDE (Chemical Dry Etching). At this time, the contact processing stopper nitride film 11 between the select gate transistors is also removed.

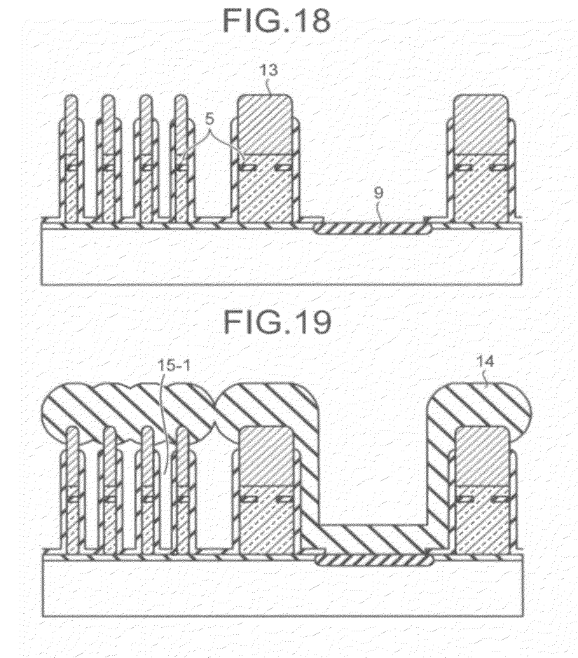

Next, as illustrated in FIG. 18, at least part of the control gate electrode 5 is made to be a silicide 13. As a silicide metal material, it is possible to use transition metals of groups 4 to 11 such as Ni, Ti, Co, Pt, Pd, Ta and Mo.

Next, as illustrated in FIG. 19, the silicon dioxide film 14 is formed by a plasma CVD method. The plasma CVD method is a deposition method with a poor implantation characteristic, and therefore an inter-word line region, in which the sacrifice nitride film 8 and the contact processing stopper nitride film 11 are removed, is not filled, so that it is possible to provide this region as the air gap 15-1. However, in the present embodiment, as illustrated in FIG. 19, the gap between the select gate transistors is filled with the silicon oxide film 14. By this means, it is possible to form the air gap 15 only between the word lines and form a shape without air gaps on a side wall portion of the select gate transistor.

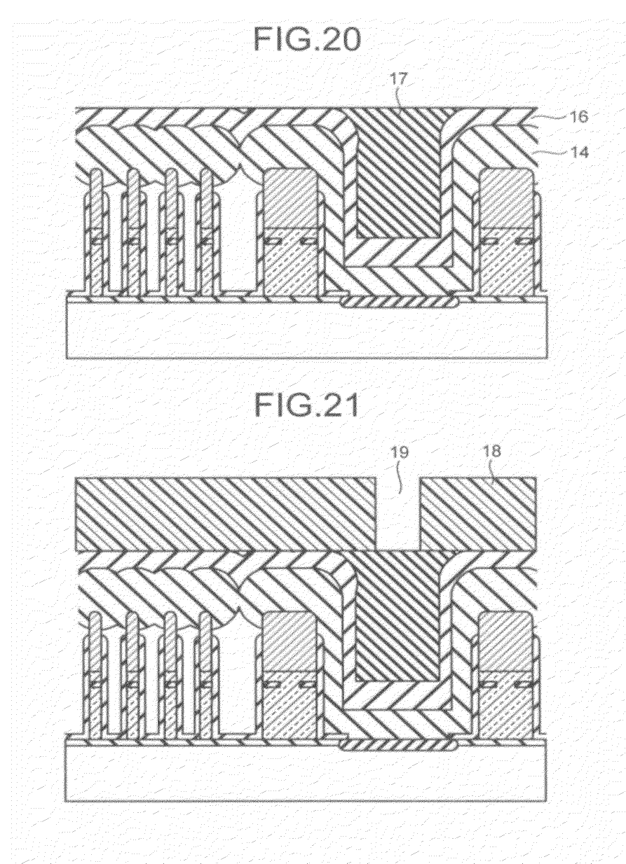

Next, as illustrated in FIG. 20, the CMP stopper nitride film 16 (i.e. silicon nitride film) and the interlayer insulating film 17 (i.e. silicon oxide film) are formed. Further, by CMP, the interlayer insulating film 17 is polished and planarization processing is performed using the silicon nitride film 16 as a stopper.

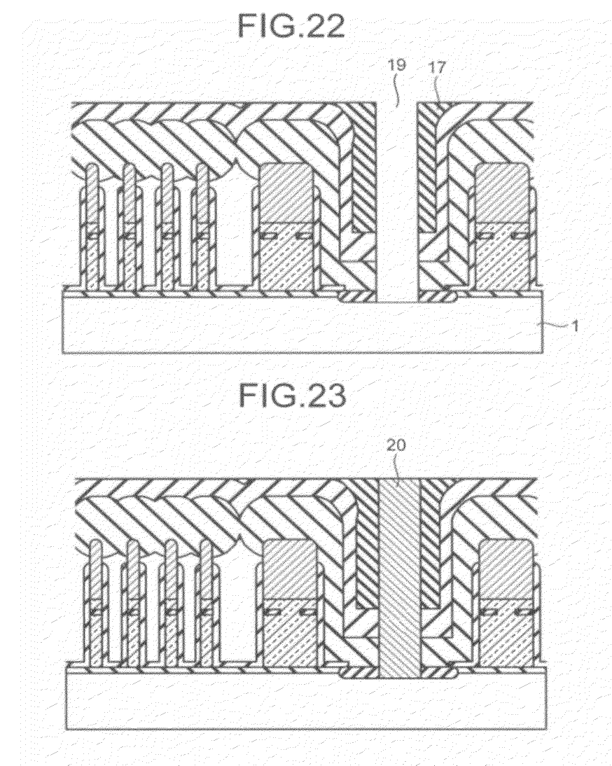

Next, as illustrated in FIG. 21, the photoresist film 18 is applied and processed by a normal lithography technique to form the hole pattern 19 for bit line contact formation. Further, as illustrated in FIG. 22, using the photoresist film 18 as a mask, the hole pattern 19 is processed by RIE to penetrate to the semiconductor substrate 1 through an SiO₂ film of the interlayer insulating film 17 and its lower layers. For example, by ashing processing, the photoresist 18 is removed.

Finally, as illustrated in FIG. 23, the wiring metal 20 such as tungsten is formed by a CVD method in the bit line contact portion to form a bit line contact.

According to the present embodiment, it is possible to avoid an obstructive factor for silicidation as in the first embodiment, and further provide an advantageous configuration for pressure resistance maintenance by forming an air gap between the word lines and shorten the distance between the select gate transistors by not forming an air gap between the select gate transistors. Therefore, for example, even in the case of shortening a bit line contact interval by bit line contact arrangement in a staggered pattern, it is possible to avoid a risk of short circuit between adjacent bit line contacts and reduce a memory region area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a plurality of element isolation regions that are formed on a semiconductor substrate and extended along a first direction in parallel;
a first insulating film that is formed on an element region between the adjacent element isolation regions on the semiconductor substrate;
a plurality of word lines that are formed at predetermined intervals in the first direction on the element region and have a charge accumulation layer, a second insulating film and a control gate electrode that are layered in order on the first insulating film;
a select gate transistor that is arranged in each of both sides of the plurality of word lines and has a width in the first direction wider than the word line;
an interlayer insulating film that is formed to cover an upper surface of the word line and the select gate transistor;
a first air gap that is positioned between the word lines and has an upper surface covered with the interlayer insulating film; and
a second air gap that is formed on a side wall portion opposite to a side of the word line of the select gate transistor and has an upper surface covered with the interlayer insulating film,
wherein an oxide film is formed on a surface of the semiconductor substrate between the select gate transistors that are adjacent to each other, and a cross-sectional surface in a second direction perpendicular to the first direction under the oxide film has a convex shape.

2. The semiconductor storage device according to claim 1, wherein the second air gap is blocked by the interlayer insulating film.

3. The semiconductor storage device according to claim 1, further comprising a third air gap that is positioned between the word line and the select gate transistor and has an upper surface covered with the interlayer insulating film.

4. The semiconductor storage device according to claim 2, further comprising a third air gap that is positioned between the word line and the select gate transistor and has an upper surface covered with the interlayer insulating film.

5. The semiconductor storage device according to claim 1, wherein a width of the select gate transistor in the first direction is three or more times as long as a width of the word line in the first direction.

6. The semiconductor storage device according to claim 2, wherein a width of the select gate transistor in the first direction is three or more times as long as a width of the word line in the first direction.

7. The semiconductor storage device according to claim 3, wherein a width of the select gate transistor in the first direction is three or more times as long as a width of the word line in the first direction.

8. The semiconductor storage device according to claim 4, wherein a width of the select gate transistor in the first direction is three or more times as long as a width of the word line in the first direction.

9. The semiconductor storage device according to claim 1, wherein at least part of the control gate electrode is silicidized.

10. The semiconductor storage device according to claim 2, wherein at least part of the control gate electrode is silicidized.

11. The semiconductor storage device according to claim 3, wherein at least part of the control gate electrode is silicidized.

12. The semiconductor storage device according to claim 4, wherein at least part of the control gate electrode is silicidized.

13. A manufacture method for a semiconductor storage device, comprising:
forming a first insulating film and a charge accumulation layer in order on a semiconductor substrate;
removing part of the charge accumulation layer, the first insulating film and the semiconductor substrate and forming a plurality of element isolation regions that extend along a first direction in parallel;
forming a second insulating film and a control gate electrode in order on the charge accumulation layer and the element isolation region;
removing the control gate electrode, the second insulating film and the charge accumulation layer between the adjacent element isolation regions at intervals in the first direction, and forming a plurality of word lines and a select gate transistor for each of both sides of the plurality of word lines, where the select gate transistor has a width in the first direction wider than the word line;
forming a spacer oxide film to cover the word line, the select gate transistor and the first insulating film;
forming a nitride film on the spacer oxide film to fill a gap between the word line and the select gate transistor;
removing part of the nitride film and the spacer oxide film to expose a surface of the semiconductor substrate between the adjacent select gate transistors without the word lines therebetween, and forming a side wall film including the spacer oxide film and the nitride film on a side wall portion opposite to a side of the word line of the select gate transistor;
thermally oxidizing the exposed surface of the semiconductor substrate between the select gate transistors;
forming a stopper nitride film on the word line, the select gate transistor, the nitride film, the thermally-oxidized film and the element isolation region;
forming an interlayer oxide film on the stopper nitride film to fill a gap between the select gate transistors;
etching to expose an upper surface of the control gate electrode and remove part of the interlayer oxide film;
removing the nitride film and part of the stopper nitride film after the etching; and
forming a air gap between the word lines and on the side wall portion, and forming an oxide film to cover an upper surface thereof after the nitride film is removed.

14. The manufacture method for the semiconductor storage device according to claim 13, wherein, in forming the select gate transistor, the select gate transistor is formed such that a width in the first direction is three or more times as long as a width of the word line in the first direction.

15. The manufacture method for the semiconductor storage device according to claim 13, wherein at least part of the control gate electrode is silicidized before the oxide film is formed.

16. The manufacture method for the semiconductor storage device according to claim 14, wherein at least part of the control gate electrode is silicidized before the oxide film is formed.

17. A manufacture method for a semiconductor storage device, comprising:
forming a first insulating film and a charge accumulation layer in order on a semiconductor substrate;
removing part of the charge accumulation layer, the first insulating film and the semiconductor substrate and forming a plurality of element isolation regions that extend along a first direction in parallel;
forming a second insulating film and a control gate electrode in order on the charge accumulation layer and the element isolation region;
removing the control gate electrode, the second insulating film and the charge accumulation layer between the adjacent element isolation regions at intervals in the first direction, and forming a plurality of word lines and a select gate transistor for each of both ends of the plurality of word lines, where the select gate transistor has a width in the first direction wider than the word line;
forming a spacer oxide film to cover the word line, the select gate transistor and the first insulating film;
forming a nitride film on the spacer oxide film to fill a gap between the word line and the select gate transistor;
removing part of the nitride film and the spacer oxide film to expose a surface of the semiconductor substrate between the adjacent select gate transistors without the word lines therebetween, and forming a side wall film including the spacer oxide film and the nitride film on a side wall portion opposite to a side of the word line of the select gate transistor;
thermally oxidizing the exposed surface of the semiconductor substrate between the select gate transistors;
forming a stopper nitride film on the word line, the select gate transistor, the nitride film, the thermally-oxidized film and the element isolation region;
forming an interlayer sacrifice film on the stopper nitride film to fill a gap between the select gate transistors;
etching to expose an upper surface of the control gate electrode and remove part of the interlayer sacrifice film;
removing the interlayer sacrifice film after the etching;
removing the stopper nitride film and the nitride film after the interlayer sacrifice film is removed; and
forming a air gap between the word lines and forming an oxide film to cover an upper surface thereof and the thermally-oxidized film after the nitride film is removed.

18. The manufacture method for the semiconductor storage device according to claim 17, wherein, in forming the select gate transistor, the select gate transistor is formed such that a width in the first direction is three or more times as long as a width of the word line in the first direction.

19. The manufacture method for the semiconductor storage device according to claim 17, wherein at least part of the control gate electrode is silicidized before the oxide film is formed.

20. The manufacture method for the semiconductor storage device according to claim 18, wherein at least part of the control gate electrode is silicidized before the oxide film is formed.
